(19) United States
(12) Patent Application Publication
(10) Pub. No.: US 2008/0031043 A1
(43) Pub. Date: Feb. 7, 2008

(54) Non-volatile memory device

(76) Inventors: Hideaki Aochi, Kanagawa-ken (JP); Yoshiaki Fukuzumi, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/822,251

(22) Filed: Jul. 3, 2007

(30) Foreign Application Priority Data
Jul. 5, 2006 (JP) 2006-185780

(51) Int. Cl. G11C 11/34; G11C 16/04; H01L 29/788

(52) U.S. Cl. 365/185.03; 365/185.01; 365/185.19; 438/257; 257/E29.3

(57) ABSTRACT

According to an aspect of the present invention, there is provided a semiconductor device including a non-volatile semiconductor memory device, including a memory cell having a electrolyte film, a first electrode and a second electrode, the electrolyte film being sandwiched between the first electrode and the second electrode, a material of the first electrode being different from a material of the second electrode, a bit line and a word line being configured as a matrix, a data-writing means having a first current source and a first counter, the first current source providing the first current to the memory cell, the first counter measuring a providing time of the first current, and a data-reading means having a second current source, a second counter and a potential sensor, the second current source providing a second current to the memory cell, the second current passing in opposed direction to the first current, the second counter measuring a providing time of the second current, the potential sensor detecting a potential, wherein writing data into the memory cell is performed by controlling the providing time of the first current corresponding to the data being written, reading the data from the memory cell is performed by detecting the providing time of the second current till a potential of the bit line equals to a prescribed potential.

### CROSS REFERENCE TO RELATED APPLICATION

This application is based upon and claims the benefit of priority from the prior Japanese Application No. 2006-185780, filed Jul. 5, 2006, the entire contents of which are incorporated herein by reference.

### FIELD OF THE INVENTION

The present invention relates to a non-volatile memory having a capability of storing multilevel data.

### DESCRIPTION OF THE BACKGROUND

Shrinking a memory cell area per one bit of a non-volatile memory device by miniaturization has lead to higher packing density of the device. However, difficulty of miniaturization in lithography technique has been increased year by year. Accordingly, for example, in a NAND flash memory or the like, multilevel-device technique has been developed. In the technique, one memory cell stores data with more than two bits.

For example, it is necessary to divide a threshold voltage width of a transistor, for example about several voltages, into four values for realizing two bits/cell. Furthermore, it is necessary to divide the threshold voltage width of the transistor into eight values for realizing three bits/cell. However, when the divided width of the threshold voltage is approach to thermal energy (25 meV) at room temperature with increasing the divided number of the threshold voltage in the transistor, the fact leads to a difficulty that the transistor retains both multilevel and reliability.

On the other hand, non-volatile memory memorizing information by using an electro-chemical reaction of an element has been well known (for example, Japanese Patent Publication (Kokai) No. 1994-28841).

A memory cell disclosed in Japanese Patent Publication (Kokai) No. 1994-28841 has a function to memorize information by using an electric conductivity change of the memory cell. The memory cell has one pair of electrodes and an electrolyte layer being sandwiched by the electrodes, and a metal is precipitated from the one electrode to the other electrode by passing a current to the memory cell.

Namely, precipitating the metal obtained by passing the current to the memory cell writes data into the memory cell. Further, checking a resistance value of the memory cell by passing a small current reads data from the memory cell. In this case, the small current passes in the reverse direction of the writing current and is vanishingly small extent as a reversible reaction.

However, the memory cell disclosed in Japanese Patent Publication (Kokai) No. 1994-28841, only memorizes data of one bit/cell with “0” or “1” utilizing resistance change with a current flow or not. The reference discloses nothing about multilevel-device technique.

Generally speaking, as a change of memory cell resistance is corresponding to passing current amount in utilizing electro-chemical reaction of an electrolyte layer memory cell, multilevel data can be memorized by making data being corresponding to the change of memory cell resistance.

However, in an IC with a power supply voltage of about several voltages, as a voltage resolution of a comparator included in the IC is not sufficient, small change of a memory cell resistance value can hardly be precisely detected so that greatly increasing a memory bit number per one cell provides a difficult problem.

### SUMMARY OF THE INVENTION

According to an aspect of the invention, there is provided a non-volatile semiconductor memory device, including, a memory cell having a electrolyte film, a first electrode and a second electrode, the electrolyte film being sandwiched between the first electrode and the second electrode, a material of the first electrode being different from a material of the second electrode, a bit line and a word line being configured as a matrix, a data-writing means having a first current source and a first counter, the first current source providing the first current to the memory cell, the first counter measuring a providing time of the first current, and a data-reading means having a second current source, a second counter and a potential sensor, the second current source providing a second current to the memory cell, the second current passing in opposed direction to the first current, the second counter measuring a providing time of the second current, the potential sensor detecting a potential, wherein writing data into the memory cell is performed by controlling the providing time of the first current corresponding to the data being written, reading the data from the memory cell is performed by detecting the providing time of the second current till a potential of the bit line equals to a prescribed potential.

Further, another aspect of the invention, there is provided, a non-volatile semiconductor memory device, including a memory cell having a electrolyte film, a first electrode and a second electrode, the electrolyte film being sandwiched between the first electrode and the second electrode, a material of the first electrode being different from a material of the second electrode, a bit line and a word line being configured as a matrix and a data-writing and data-reading means having a first current source, a second current source, a counter and a potential sensor, the first current source providing the first current to the memory cell, the second current source providing a second current to the memory cell, the second current passing in the opposite direction to the first current, the counter measuring a providing time of the first current or the second current, the potential sensor detecting a potential, wherein writing data into the memory cell is performed by controlling the providing time of the first current corresponding to the data being written, and reading the data from the memory cell is performed by detecting the providing time of the second current till a potential of the bit line equals to a prescribed potential.

Further, another aspect of the invention, there is provided, a method of fabricating a non-volatile semiconductor memory device including, forming a cell transistor on a semiconductor substrate, the cell transistor being covered by an interlayer dielectric layer, forming a bit line on the interlayer dielectric layer, forming a contact plug in the interlayer dielectric layer, the contact plug connecting a source of the cell transistor, forming a memory cell over the bit line via the interlayer dielectric layer, the memory cell having a first electrode, an electrolyte film and a second electrode.

### BRIEF DESCRIPTION OF THE DRAWINGS

FIG. 1 is a block diagram showing a configuration of a non-volatile memory device according to a first embodiment of the present invention;

FIG. 2 is a cross-sectional view showing a structure of a memory cell array in the non-volatile memory device according to the first embodiment of the present invention;

FIG. 3 is a cross-sectional view showing a memory cell of the non-volatile memory device according to the first embodiment of the present invention;

FIG. 3(a) is a cross-sectional view showing an initial state written data “0” in;

FIG. 3(b) is a cross-sectional view showing a state written data “1” in;

FIG. 3(c) is a cross-sectional view showing a state written data “2” in;

FIG. 3(d) is a cross-sectional view showing a state written data “255” in;

FIG. 4 shows a relationship between a pulse number of the writing current and a resistance of the memory cell according to the first embodiment of the present invention;

FIG. 5 is a cross-sectional view showing the memory cell of the non-volatile memory device according to the first embodiment of the present invention;

FIG. 5(a) is a cross-sectional view showing a state of the memory cell being at starting point for reading out;

FIG. 5(b) is a cross-sectional view showing a state of the memory cell being at ending point for reading out;

FIG. 6 shows a relationship between the pulse number of the writing current and the resistance of the memory cell according to the first embodiment of the present invention;

FIG. 7 is a flow chart showing processing steps for writing data in the memory cell of the non-volatile memory device according to the first embodiment of the present invention;

FIG. 8 is a flow chart showing the processing steps for reading out the data from the memory cell of the non-volatile memory device according to the first embodiment of the present invention;

FIG. 9 is a block diagram showing a configuration of a non-volatile memory device according to a second embodiment of the present invention;

FIG. 10 is a block diagram showing a configuration of a non-volatile memory device according to a third embodiment of the present invention;

FIG. 11 is a block diagram showing a configuration of a reading means of the non-volatile memory device according to the third embodiment of the present invention;

FIG. 12 is a block diagram showing a configuration of a writing means of a non-volatile memory device according to a fourth embodiment of the present invention;

FIG. 13 is a block diagram showing a configuration of a reading means of the non-volatile memory device according to a fourth embodiment of the present invention.

### DETAILED DESCRIPTION OF THE INVENTION

Embodiments of the present invention will be described below in detail with reference to the attached drawings. It should be noted that the present invention is not restricted to the embodiments but covers their equivalents. Throughout the attached drawings, similar or same reference numerals show similar, equivalent or same components.

### First Embodiment

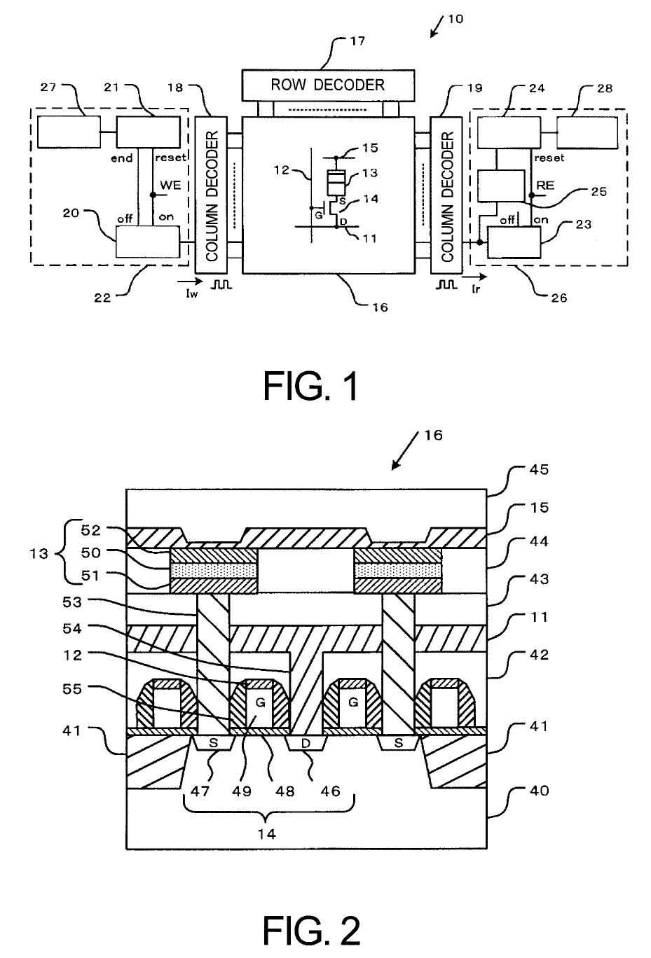

First, a non-volatile memory device according to a first embodiment of the present invention will be described below in detail with reference to FIG. 1 and FIG. 2. FIG. 1 is a block diagram showing a configuration of the non-volatile memory device. FIG. 2 is a cross-sectional view showing a structure of a memory cell array in the non-volatile memory device.

As shown in FIG. 1, the non-volatile memory device 10 according to the first embodiment provides a memory cell array 16. The memory cell array 16 provides a bit line 11, a word line 12, a memory cell 13, a cell transistor 14 and a common wiring 15. The bit line 11 and the word line 12 are arranged as a matrix. The memory cell 13 and the cell transistor 14 are disposed at an orthogonal portion between the bit line 11 and the word line 12. The memory cell 13 has an electrolyte film, a first electrode and a second electrode. The first electrode and the second electrode are formed on both surface sides of the electrolyte film; each of the electrodes is formed as a different material. The cell transistor 14 has a drain D, a source S and a gate G. The drain D is connected to the bit line 11. The source S is connected to one electrode of memory cell 13. The common wiring 15 is connected to the other electrode of the memory cell 13. The gate G is connected to the word line 12.

Further, the non-volatile memory device 10 provides a row decoder 17, column decoders 18, 19, a data writing-means 22 and a data-reading means 26. The row decoder 17 and the column decoders 18, 19 select one of the memory cells 13 in the memory cell array 16. The data writing means 22 provides a first current source 20 and a first counter 21. The first current source 20 provides a first current to the selected first memory cell 13. The first counter 21 measures a providing time of the first current. The data-reading means 26 provides a second current source 23, a second counter 24 and a potential sensor 25. The second current source 23 provides a second current flowing to oppose direction of the first current to the selected memory cell 13. The second counter 24 measures a providing time of the second current. The potential sensor 25 detects a potential change of the bit line 11.

Further, the data-writing means 22 provides a first buffer 27. The first buffer 27 accepts data selected by the row decoder 17 and the column decoder 18 from an outer portion and stores the data into the memory cell data 13. The data-reading means 26 provides a second buffer 28. The second buffer 28 stored the data selected by the row decoder 17 and the column decoder 19 from the memory cell 13 and output the data to the outer portion.

The data-writing means 22 applies the writing current Iw (first current) to the memory cell 13 with an initial stage as pulses corresponding to a number of the data stored in the first buffer 27 so as to write the data into the memory cell 13 selected by the row decoder 17 and the column decoder 18.

The data-reading means 26 applies a reading current Ir (second current) to the memory cell 13 selected by the row decoder 17 and the column decoder 19 as pulses so as to read out the data from the memory cell 13 by counting a number of counted pulses till the memory cell 13 being back to the initial state and stores the data in the second buffer 28.

Actually, the data-writing means 22 sets the writing data from the first buffer 27 to the first counter 21, when receiving a writing signal WE.

Next, the first current source 20 starts to provide the writing current Iw. The first counter 21 starts to count down on a clock number. When the count number reaches to zero, the first counter 21 transmits an ending signal END and the first current source 20 stop to provide the writing current Iw.

When the data-reading means 26 receives a reading signal RE, the second current source 23 starts to provide a reading current Ir and the second counter 24 starts to count up on the clock number.

Next, when the potential sensor 25 is operated by increasing potential of the bit line 11, a reading signal RE becomes to an inactive state as comparing with the preserved potential Vref (not illustrated), so that the second current source 23 stop to provide the reading current Ir and the second counter 24 transfers the count value to the second buffer 28.

As shown in FIG. 2, the memory cell array 16 is formed on a semiconductor substrate 40, for example, a silicon substrate. Two cell transistors 14 having a common drain D is formed in an area surrounded by an isolation layer 41 of the semiconductor substrate 40. The bit line 11 is formed over the cell transistor 14 via an interlayer dielectric film 42, for example TEOS (Tetra Ethyl Ortho Silicate) film. The memory cell 13 is formed over the bit line 11 via an interlayer dielectric film 43. The common wiring 15 is formed over an interlayer dielectric film 44. The common wiring 15 is covered by an insulator 45.

The cell transistor 14 provides a drain diffusion layer 46 and a source diffusion layer 47 separately formed in the semiconductor substrate 40, a gate insulator 48, for example, a silicon oxide film between the drain diffusion layer 46 and the source diffusion layer 47, and a gate electrode 49, for example, a poly-crystalline silicon film formed on the gate insulator 48.

The memory cell 13 provides an electrolyte film 50, for example, sulfide silver (Ag₂S), a first electrode 51, for example silver (Ag), formed on a rower surface of the electrolyte film 50, a second electrode 52, for example platinum (Pt), is formed an upper surface of the electrolyte film 50.

The first electrode 51 of the memory cell 13 is connected to the source diffusion layer 47 of the cell transistor 14 via a contact plug 53. The second electrode 52 of the memory cell 13 is connected to the common wiring 15.

The drain diffusion layer 46 of the cell transistor 14 is connected to the bit line 11 via a via hole 54. The word line 12 is formed on the gate electrode 49 of the cell transistor 14. Side surfaces of the word line 12 and side surfaces of the gate electrode 49 are covered by a side-wall film 55.

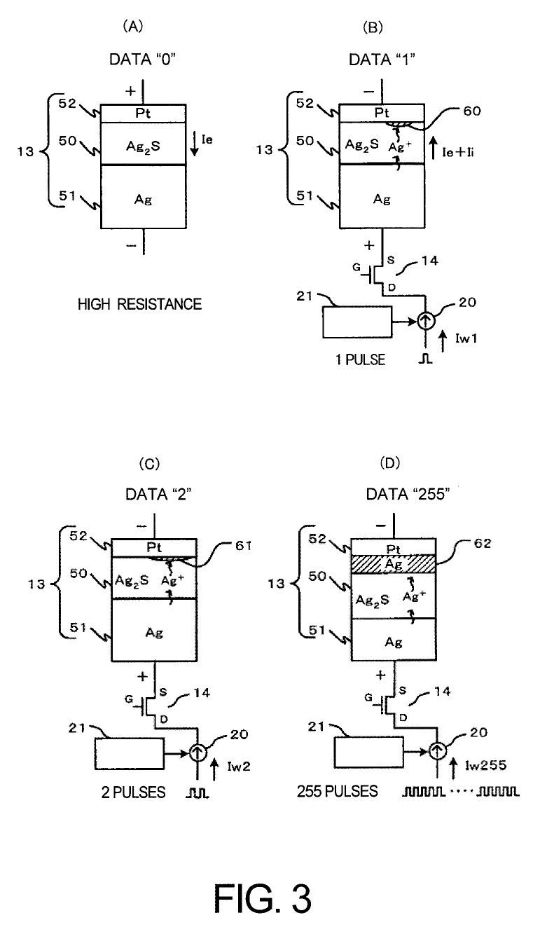

FIG. 3 is a cross-sectional view showing the memory cell 13 of the non-volatile memory device 10 in which multilevel data are written. FIG. 3(a) is a cross-sectional view showing an initial state written data “0” in. FIG. 3(b) is a cross-sectional view showing a state written data “1” in. FIG. 3(c) is a cross-sectional view showing a state written data “2” in. FIG. 3(d) is a cross-sectional view showing a state written data “255” in.

As shown in FIG. 3(a) as the initial stage of the memory cell 13, the first electrode 51 of the memory cell 13 connect to a row potential side and the second electrode 52 of the memory cell 13 connect to a high potential side. When a current passes from the second electrode 52 to the first electrode 51, the current in the memory cell 13 is only an electron current Ie, and the memory cell 13 show a high resistance state (Rm0). This stage in this embodiment is called that data “0” is memorized in the memory cell 13.

As shown in FIG. 3 (b), the first electrode 51 of the memory cell 13 connects to the high potential side, and the second electrode 52 of the memory cell 13 connects to the row potential side. After the cell transistor 14 is switched on, the current passes from the first electrode 51 to the second electrode 52. Furthermore, the current in the memory cell 13 is an ion current Ii caused by ion (Ag⁺, S²⁻) in the electrolyte film 50 in addition to the electron current Ie so that an electrode reaction is generated.

Silver ion (Ag⁺) in the electrolyte film 50 precipitates on the second electrode 52 by the electrode reaction after reaching to the second electrode 52 so that a metal (Ag) precipitate 60 is formed on the second electrode 52. Simultaneously, silver (Ag) in the first electrode 51 dissolves into the electrolyte film 50 by an electrode reaction, accordingly, silver ion (Ag⁺) concentration is steadily retained in the electrolyte film 50.

Generation of the metal precipitate 60 on the first electrode 51 causes barrier height change between the second electrode 52 and the electrolyte film 50, as a result, a resistance of the memory cell 13 is changed so as to sift to a row resistance state.

Therefore, the memory cell 13 have a rower resistance Rm1 than resistance Rm0 at the initial stage by passing a pulse current Iw1 with one clock as the writing current Iw with a stationary current. This stage in this embodiment is called that data “1” is memorized in the memory cell 13.

As shown in FIG. 3(c), a metal precipitate 61 being larger than the metal precipitate 60 is generated by passing a pulse current Iw2 with two clocks as the writing current Iw so that the memory cell 13 presents a resistance Rm2 rower than the resistance Rm1. This stage in this embodiment is called that data “2” is memorized in the memory cell 13.

As shown in FIG. 3(d), a metal precipitate 62 being larger than the metal precipitate 61 is totally generated on the second electrode 52 by passing a pulse current Iw 255 with 255 clocks as the writing current Iw, so that the memory cell 13 presents a resistance Rm255 rower than the resistance Rm2. This stage in this embodiment is called that data “255” is memorized in the memory cell 13.

Furthermore, a clock signal is provided from a clock signal generation circuit built in the non-volatile memory device 10. However, the clock signal may be provided from an outer region, for example, a computer system being connected with the non-volatile memory device 10.

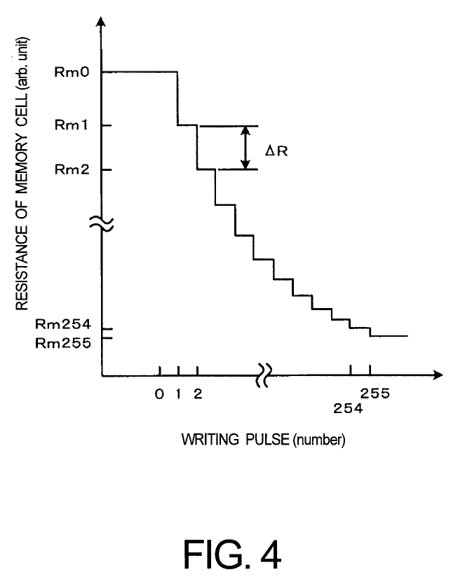

FIG. 4 shows a relationship between a pulse number of the writing current Iw applied to the memory cell 13 of the non-volatile memory device 10 and a resistance of the memory cell 13.

As shown in FIG. 4, the memory cell 13 is a high resistance state in the initial state. By applying a pulse of the writing current Iw to the memory cell 13 step by step, the resistance is lowered as a step-like state so that a stair of step ΔR decreases with decreasing the resistance.

As mentioned above, Rm0 shows a resistance at the initial state. Further, Rm1 shows a resistance at the state of applying the writing current Iw with one pulse, Rm2 shows a resistance at the state of applying the writing current Iw with two pulses, Rnm254 shows a resistance at the state of applying the writing current Iw with 254 pulses, Rm255 shows a resistance at the state of applying the writing current Iw with 255 pulses.

From the discussion mentioned above, writing the data on the memory cell 13 is conducted along the pulse number of the writing current Iw, therefore, resetting the data of the memory cell 13 at the initial state data “0” is necessary before starting to write the data.

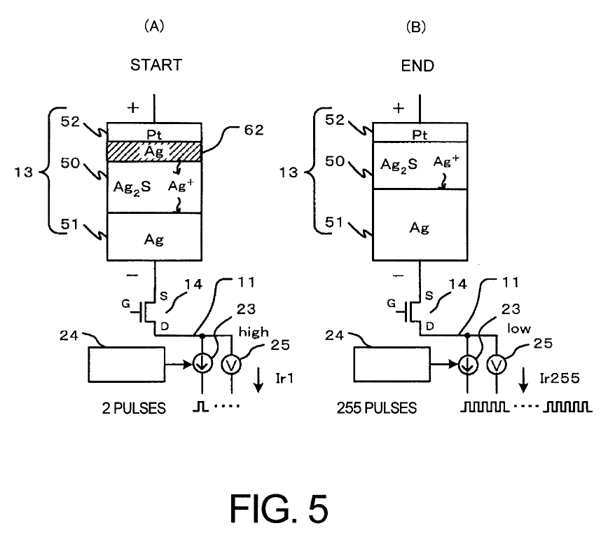

FIG. 5 is a cross-sectional view showing the memory cell 13 of the non-volatile memory device 10 in which multilevel data are read out.

FIG. 5(a) is a cross-sectional view showing a state of the memory cell 13 being at starting point for reading out. FIG. 5 (b) is a cross-sectional view showing a state of the memory cell 13 being at ending point to for reading out. Here, the data “255” is memorized in the memory cell 13.

The multilevel data memorized in the memory cell 13 is read by a following process steps. The first electrode 51 connects to the low potential side and the second electrode 52 connects to the high potential side so that the reading current Ir with a stationary current passes towards the opposite direction against the writing current Iw passing from the second electrode 52 to the first electrode 51.

as shown in FIG. 5(a), an electrode reaction in the memory cell 13 being reverse to the writing step is generated by applying the reading current Ir with a pulse. Silver ion (Ag⁺) in the electrolyte film 50 precipitates on the first electrode 51. On the other hand, the metal (Ag) precipitate 62 on the second electrode 52 dissolves into the electrolyte film 50.

In the way mentioned above, a resistance of the memory cell 13 increases accompanying with the pulse number applied to the memory cell 13 so that the potential of the bit line 11 is lowered.

As shown in FIG. 5(b), the second counter 24 counts the pulse number applied to the memory cell 13 and the potential sensor 25 monitors the potential of the bit line 11. The data reading means 26 detects the state when the resistance of the memory cell 13 returns Rm0 at the initial state and the reading data corresponding to a count value is determined.

When the electron current Ie is much larger than the ion current Ii, an absolute value of the writing current Iw is set to the same as an absolute value of the reading current Ir. As the writing pulse number equals to the reading pulse number, the data read out is determined as “255”.

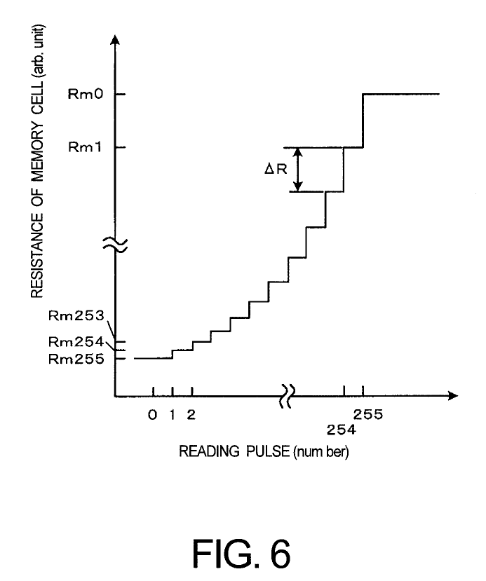

FIG. 6 shows a relationship between the pulse number of the writing current Iw applied to the memory cell 13 of the non-volatile memory device 10 and the resistance of the memory cell 13. As shown in FIG. 6, the memory cell 13 is the row resistance state at starting point of reading data. As shown in FIG. 6(a), applying the reading current Ir as a pulse to the memory cell 13 step by step, the resistance is increased as a step-like state, so that a stair of step ΔR increases with increasing the resistance.

As mentioned above, Rm255 shows the resistance at the starting of reading data. Further, Rm254 shows the resistance at the state of applying the reading current Ir with one pulse, Rm253 shows the resistance at the state of applying the reading current Ir with two pulses, Rm1 shows the resistance at the state of applying the reading current Ir with 254 pulses and Rm0 shows the resistance at the state of applying the reading current Ir with 255 pulses.

From the discussion mentioned above, as reading the data from the memory cell 13 is conducted reverse to the writing the data. Accordingly, the data are reset at “0” when reading is finished. Therefore, refreshing, which means rewriting the data into the memory cell 13, is necessary after reading out the data from the memory cell 13.

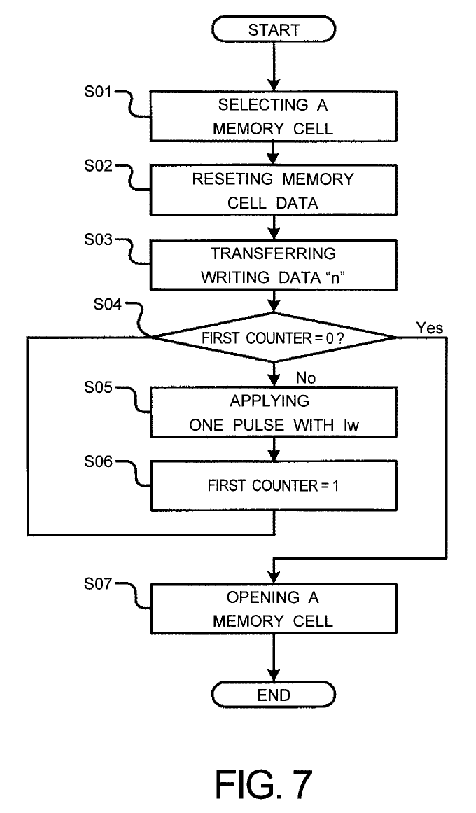

FIG. 7 is a flow chart showing processing steps for writing data in the memory cell 13 of the non-volatile memory device 10. As shown in FIG. 7, the memory cell 13 being written the data in the memory cell array 16 is addressed by the word line 12 and the bit line 11, and the memory cell 13 is selected by the row decoder 17 and the column decoder 18 (step S01).

Next, a reset current (third current) passes from the second electrode 52 towards the first electrode 51. As a result, the data in the selected memory cell 13 to “0” (step S02) is reset. The reset current may be the same as the reading current Ir, however, a larger reset current may be favorable for shortening the reset time. Next, the written data “n” transfers from the first buffer 27 to the first counter 21 (step S03).

Next, the first counter 21 being 0 or not is checked (step S04). If the first counter 21 is not 0 (step S04 is “No”.), the memory cell 13 is applied by one pulse of the writing current Iw (step S05). After one is subtracted from the first counter 21 (step S06), the process goes back to step S04, and after that step S05 and step S06 are executed.

On the other hand, if the first counter 21 is 0 (step S04 is “Yes”.), the address by the word line 12 and the bit line 11 is cancelled, so that the selected memory cell 13 is opened (step S07).

As the processing steps mentioned above, the metal precipitate corresponding to data “n” is generated on the second electrode 52 of the memory cell 13 and the written data “n” is finally finished.

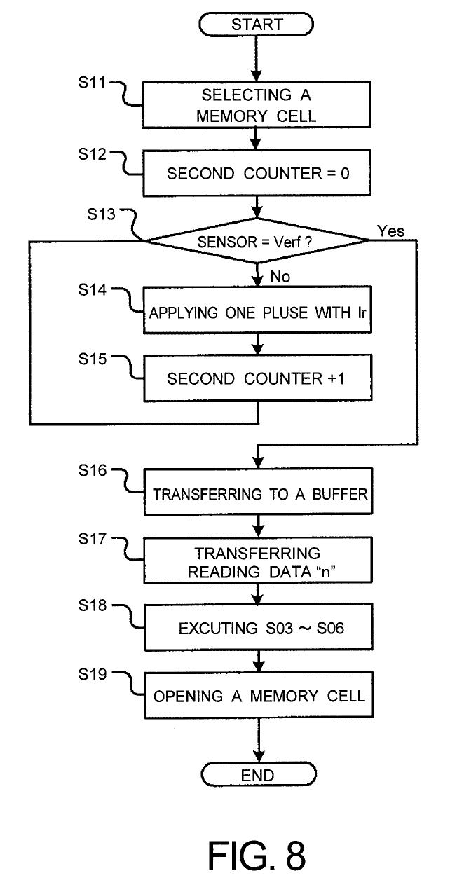

FIG. 8 is a flow chart showing processing steps for reading out the data from the memory cell 13 of the non-volatile memory device 10. As shown in FIG. 8, the memory cell 13 reading out the data in the memory cell array 16 is addressed by the word line 12 and the bit line 11 and is selected by the row decoder 17 and the column decoder 18 (step S11). Next, the second counter 24 is reset to 0 (step S12).

Next, a potential of the bit line 11 is monitored by the potential sensor 25 and is compared with preserved standard voltage Vref (step S13). If the potential of the bit line 11 is larger than standard voltage Vref (step S13 is “No”.), one pulse of the reading current Ir is applied to the memory cell 13 (step S14). One is added to the second counter 24 (step S15). After the process goes back to step S13, step S14 and step S15 is executed.

On the contrary, if the potential of the bit line 11 is equal to the standard voltage Vref (step S13 is “Yes”.), a counter value of the second counter 24 transfer to the second buffer 28 (step S16).

Next, the counter value of the second counter 24 transfers from the second buffer 28 to the first counter 21 (step S18). A data-writing-sequence from step S03 to step S06 are executed. The reading data written back to the selected memory cell 13 are refreshed (step S18).

Next, the address by the word line 12 and the bit line 11 is cancelled, so that the memory cell 13 selected is opened (step S19). As the processing steps mentioned above, the metal precipitate temporally removed is generated again on the second electrode 52 of the memory cell 13, so that reading the data “n” is finally finished.

As an explanation mentioned above, the non-volatile memory device 10 in this embodiment has the memory cell 13 including the electrolyte film 50, the first electrode 51 and the second electrode 52. The first electrode 51 and the second electrode 52 are formed on both sides of the electrolyte film, each of the electrodes is formed as a different material.

The data are written to the memory cell 13 by controlling the providing time of the writing current Iw and the data are read by detecting the providing time of the reading current Ir till the potential of the bit line 11 equals to a preserved potential.

Accordingly, as a pulse number of the writing current Iw and the reading current Ir is counted without directly detecting the resistance change of the memory cell 13, a bit number memorized per one cell can be greatly increased. As a result, the non-volatile memory device 10 having a capability of writing and reading multilevel data is obtained.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

Here, it is explained that the multilevel data from “1” to “255” are written into the memory cell 13. However, writing, which namely means the metal (Ag) precipitate on the first electrode 51, is conducted by precisely dissolving the same silver (Ag) content of the first electrode 51 into the second electrode (Pt) 52 being opposed to the first electrode 51. Therefore, the writable multilevel data cannot be principally restricted by fully having a volume of the first electrode 51.

Further, it is explained that the writing current Iw is equal to the reading current Ir. However, another case that the writing current Iw differs from the reading current Ir, may be acceptable. For example, if the electron current Ie is nearly the same as the ion current Ii, |Iw|<|Ir| may be desirable. However, the relation between |Iw| and |Ir| can suitably be determined by the gate leak current of the cell transistor 14, an area ratio between the first electrode 51 and the second electrode 52 or the like.

Further, it is explained that the writing current Iw and the reading current Ir are the pulse currents, however, another case that the writing current Iw and the reading current Ir being direct currents may be acceptable. The direct current has an advantage that a writing time and a reading time can be shortened as comparing with the pulse current.

Metal oxide, chalcogenide compound or halide compound can be used as the electrolyte film 50, however, the electrolyte film 50 including constituting element of the first electrode 51 may be desirable. Moreover, a oxide of 3d and 4d transition metal or chalcogenide compound may be desirable. The electrolyte film 50 is not necessary a solid but a liquid electrolyte, if fabricating process can be acceptable. A compound system over ternary including a plurality of metal elements can be used as the metal oxide, the chalcogenide compound or the halide.

Further, it is explained that silver (Ag) is used as the first electrode 51, however, another metal, for example, 3d and 4d transition metal, alkali metal such as Na, Li, Mg or the like, alkali earth metal, aluminum or the like can be used. Furthermore, conductive compounds of 3d and 4d transition metal, alkali metal such as Na, Li or the like, alkali earth metal such as Mg or the like and aluminum or the like may be acceptable as mentioned below. it is explained that platinum (Pt) is used as the second electrode 52, however, another inactive and conductive film, for example, gold (Au), iridium (Ir), osmium (Os), palladium (Pd), rhodium (Rh), ruthenium (Ru) et. al. as noble metal or for example, Ti (Ti), tantalum (Ta), tungsten (W) or the like as a metal, its nitride or the like.

The memory cell 13 may have a space in the electrolyte film 50 or an interface between the electrolyte film 50 and the first or the second electrode 51, 52. This method has an advantage that the resistance change content ΔR of the memory cell 13 can be larger than that of a conventional electrolyte film.

Further, it is explained that the first electrode 51 is formed on the rower surface of the electrolyte film 50 in the memory cell 13 and the second electrode 52 is formed on the upper surface of the electrolyte film 50 in the memory cell 13. However, the first electrode 51 and the second electrode 52 can be exchanged each other. Further, it is explained that positive ion (Ag⁺) is precipitated. However, accumulation of a negative ion, such as an oxygen ion, a hydroxide ion or the like can be used as information. In this case, polarity mentioned above may be suitably reversed.

Moreover, the writing current Iw and the reading current Ir are assigned at a relatively larger value to obtain higher speed on writing and reading operation of the memory cell 13. In this case, after repeating operations of the memory cell 13, an interface between the first electrode 51 and the electrolyte film 50 is roughened to produce concavity and convexity. As a result, an operation defect, mainly a shortage between wirings, is caused.

As an action in this case, conductivity of Ag ion in the first electrode 51 contributing to memory operation is made larger than conductivity of Ag ion in the electrolyte film 50 is effective.

For example, using Ag₂S/Ag layered structure as the first electrode 51, Ag—WO₃ as the electrolyte film 50 and Pt or W as the second electrode 52 produces that Ag ion conductivity of the first electrode 51 in Ag₂S is larger than that of the first electrode 51 in Ag—WO₃.

In this way, at the resetting and reading operation, as Ag ion precipitate in the interface between the first electrode 51 and the electrolyte film 50 is rapidly absorbed in the first electrode 51 and diffuses into the first electrode 51, the interface between the first electrode 51 and the electrolyte film 50 is flatly retained. As a result, reliability in repeatedly operating the memory cell 13 is improved.

Furthermore, the potential is basically not in the memory cell 13 between a data retaining period after writing the data, accordingly an element is retained at equilibrium state in the writing state. A conventional Dynamic Random Access Memory (DRAM) or a conventional flash memory has necessarily the potential in the element on data writing state. Therefore, a leak current towards a direction for softening the potential is a problem. However, as the element itself does not store energy in the memory cell 13, data retention characteristic is largely improved.

Refreshing for writing again may be performed to only the memory cell 13 read the data. For example, consumption power can be reduced as comparing with DRAM being essentially refreshed the all memory cells.

Moreover, the potential of the bit line 11 may be retain at the potential of the common wiring 15 about the memory cell 13 without reading the data. As a result, improvement of data retention characteristic can be expected.

For improving data retention reliability on non-access, for example, an operation condition in standby may equal to the potential of second electrode 52, the equalize potential of bit line 11, the well potential of cell transistor 14, so that it is desirable to strongly decrease the current memory cell 13 off-leakage current or junction-leakage current of cell transistor 14.

Further, it is explained that the drain D connect to the bit line 11, the source S connect to the first electrode 51 in the memory cell 13, drain D connect to the first electrode 51 of the memory cell 13, source S connect to the bit line 11.

### Second Embodiment

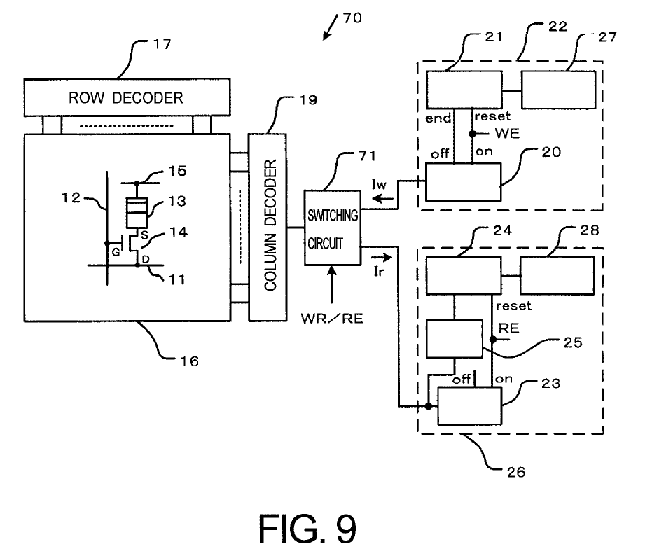

FIG. 9 is a block diagram showing a configuration of a non-volatile memory device according to a second embodiment of the present invention. In the second embodiment, a portion of a similar or same composition as the first embodiment is attached the similar or same number. Further, explanation of the portion of the similar or same composition is omitted and the portion of the different composition is explained.

A different point in the second embodiment is to configure a switching circuit which connects a data-writing means or a data-reading means to a column decoder.

As shown in FIG. 9, a non-volatile memory device 70 in this embodiment provides the switching circuit 71, for example a MOS transistor, connecting the data writing means 22 or the data-reading means 26 to the column decoder 19.

When the switching circuit 71 receives a signal WR instructing to write data into the memory cell 13, the switching circuit 71 connects the data writing means 22 to the column decoder 19. The data writing means 22 provides the writing current Iw into the memory cell 13 via the switching circuit 71.

On the other hand, when the switching circuit 71 receives a signal RE instructing reading the data from the memory cell 13, the switching circuit 71 connects the data-reading means 26 to the column decoder 19. The data-storing portion means 26 provides the reading current Ir into the memory cell 13 via the switching circuit 71.

In this way, writing and reading of data can be conducted for the memory cell 13 selected by the row decoder 17 and the column decoder 19.

As mentioned above, the non-volatile semiconductor device 70 in this embodiment share the column decoder 19 as writing the data and reading the data. Accordingly, the non-volatile semiconductor device 70 has an advantage to include the only one column decoder so as to shrink a chip size.

### Third Embodiment

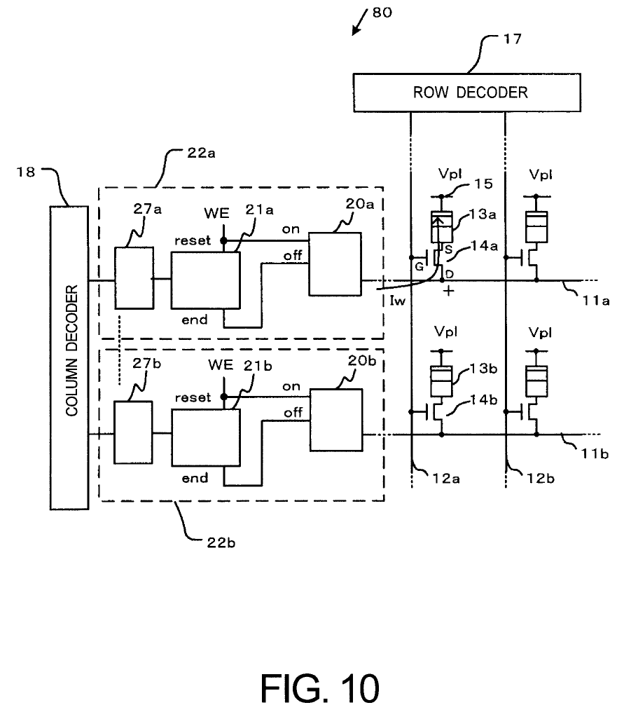

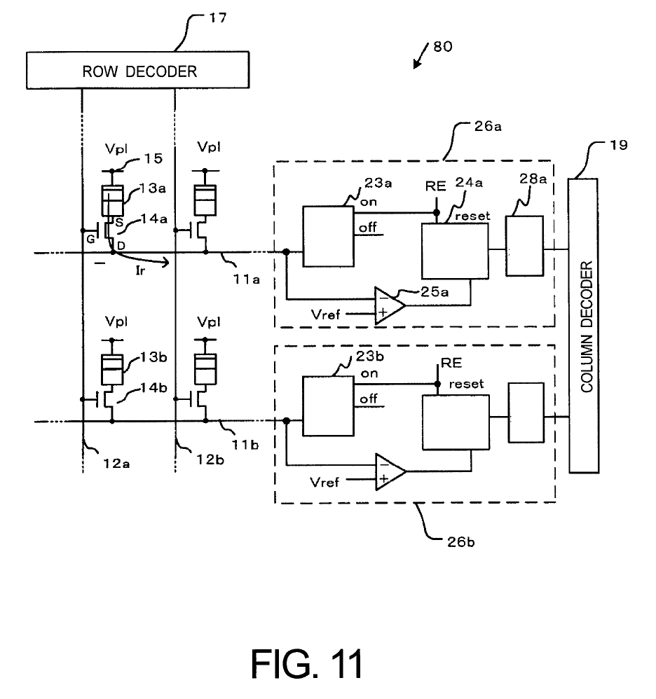

FIG. 10 and FIG. 11 are diagrams showing a main portion of a non-volatile memory device, respectively, according to a third embodiment of the present invention. FIG. 10 is a block diagram showing a configuration of the non-volatile memory device according to the third embodiment of the present invention. FIG. 11 is a block diagram showing a configuration of a reading means of the non-volatile memory device according to the third embodiment of the present invention.

In the third embodiment, a portion of a similar or same composition as the first embodiment is attached the similar or same number. Further, explanation of the portion of the similar or same composition is omitted and the portion of the different composition is explained.

A different point in the third embodiment is to dispose the data writing means and the data-reading means on every bit line.

As shown in FIG. 9, a non-volatile memory device 80 in this embodiment is connected between the column decoder 18 and the bit line 11. The non-volatile memory device 80 has a plurality of the data writing means 22 and provides the writing current Iw to the memory cell 13.

Actually, a data writing means 22a is connected between the column decoder 18 and a bit line 11a, and a data writing means 22b is connected between the column decoder 18 and a bit line 11b.

First, instructing the word line 12a by the row decoder 17 and the bit line 11a by the column decoder 18 select a memory cell 13a. Next, a first current source 20a receives the writing signal WE and sets the writing data from a first buffer 27a to a first counter 21a. Next, when the first current source 20a outputs the writing current Iw, the first counter 21a starts down-count of a clock number. Next, when the first counter 21a reaches to zero, an end signal is generated and the first current source 20a stops to provide the writing current Iw.

Here, the output current is set to zero or a potential Vp1 of the common wiring 15 is output with respect to a first current source 20b of a non-selected bit line 11b. In this case, a cell transistor 14b is put off so that the data of a memory cell 13b is unchanged.

In this way, writing the data can be conducted for the memory cell 13 selected by the row decoder 17 and the column decoder 19.

As shown in FIG. 11, the non-volatile memory device 80 in this embodiment is connected between the column decoder 18 and the bit line 11. The non-volatile memory device 80 has a plurality of data-reading means 26 and provides the reading current Ir to the memory cell 13.

Actually, a data-reading means 26a is connected between the column decoder 18 and a bit line 11a, and a data-reading means 26b is connected between the column decoder 18 and a bit line 11b.

First, instructing the word line 12a by the row decoder 17 and the bit line 11a by the column decoder 19 selects a memory cell 13a. Next, a second current source 23a receives the reading signal RE and start to output the reading current Ir. A second counter 24a starts to up-count of a clock number. Next, when a potential of the bit line 11a becomes larger than preserved potential Vref, a potential sensor 25a operates. The reading signal RE is inactive so that the second current source 23a stops to provide the reading current Ir and the second counter 24a sends the count value to a second buffer 28a.

Here, the output current is set to zero or the potential Vp1 of the common wiring 15 is output with respect to a second current source 23b of the non-selected bit line 11b. In this case, a cell transistor 14b is put off so that the data of a memory cell 13b is unchanged.

In this way, reading the data can be conducted for the memory cell 13 selected by the row decoder 17 and the column decoder 19.

As mentioned above, the non-volatile semiconductor device 80 in this embodiment configures the data writing means 22 and the data-reading means 26 on every bit line. As a result, the non-volatile semiconductor device 80 has an advantage to be able to continuously and speedy write the data by preliminarily storing the data for writing. Furthermore, the non-volatile semiconductor device 80 has another advantage to be able to continuously and speedy read the data by reserving in the second buffer 28 without transferring the read data to outer region in each case.

Here, main operations of each portion are explained. Furthermore, latch or the like may timely is disposed for maintaining timing between the portions.

### Fourth Embodiment

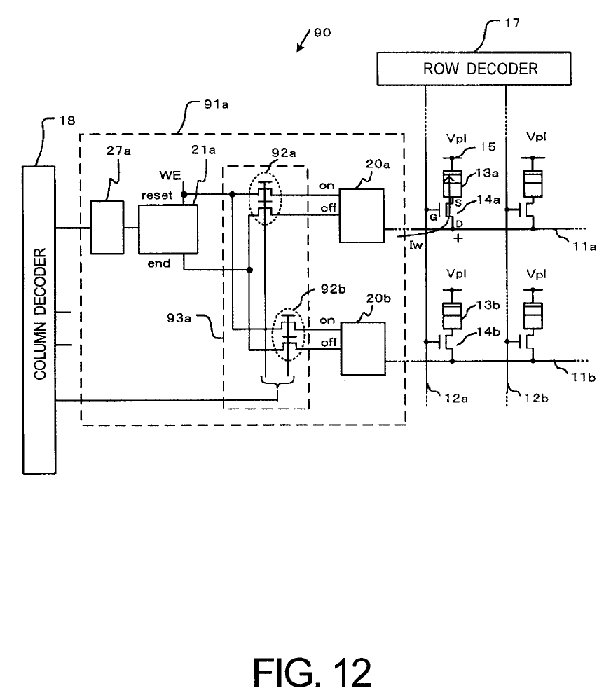

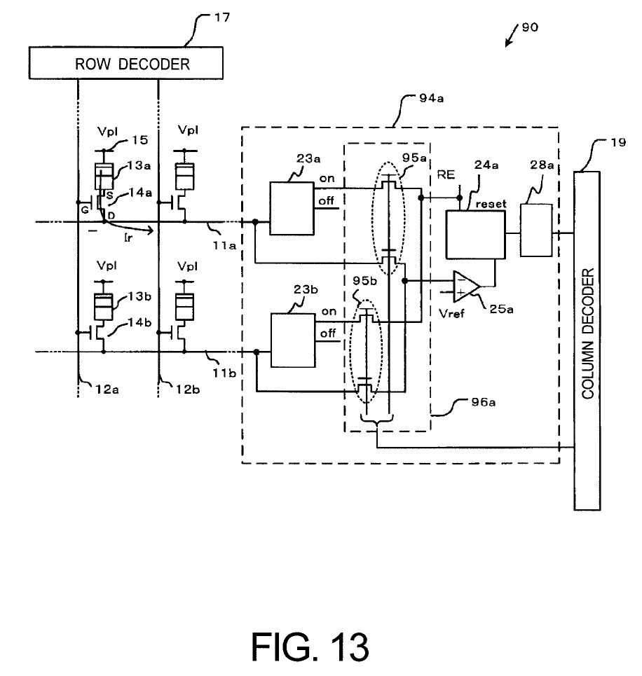

FIG. 12 and FIG. 13 are diagrams showing a main portion of a non-volatile memory device, respectively, according to a third embodiment of the present invention. FIG. 12 is a block diagram showing a configuration of a writing means of the non-volatile memory device according to a fourth embodiment of the present invention;

FIG. 13 is a block diagram showing a configuration of a reading means of the non-volatile memory device according to the fourth embodiment of the present invention.

In this embodiment, a portion of a similar or same composition as the first embodiment is attached the similar or same number. Further, explanation of the portion of the similar or same composition is omitted and the portion of the different composition is explained.

A different point in the first embodiment is to dispose the data writing means and the data-reading means on every bit line.

As shown in FIG. 12, a non-volatile memory device 90 in this embodiment is connected between the column decoder 18 and the bit line 11. The non-volatile memory device 90 has a plurality of data writing means 22 and provides the writing current Iw to the memory cell 13.

Actually, a data writing means 22a is connected between the column decoder 18 and a bit line 11a, and provide the writing current Iw to a memory cell 13a or a memory cell 13b. The data writing means 92b (not shown) is connected between the column decoder 18 and a bit line 11c. The data writing means 92b also is connected between the column decoder 18 and the bit line 1d. The data writing means 92b provide the writing current Iw to a memory cell 13c (not shown) or a memory cell 13d (not shown).

The data writing means 91a provides a switching circuit 93a having a switch 92a and a switch 92b. The switch 92a connects between the first counter 21a and the first current source 20a. The switch 92b connects between the first counter 21a and the first current source 20b. The switching circuit 93a connects the first counter 21a to the first current source 20a, when the switch 92a is on and the switch 92b is off. Further, the switching circuit 93a connects the first counter 21a to the first current source 20b, when the switch 92a is off and the switch 92b is on.

In this way, writing data can be conducted for the memory cell 13 selected by the row decoder 17 and the column decoder 19.

As shown in FIG. 13, the non-volatile memory device 90 of this embodiment is connected between the column decoder 19 and a plurality of the bit line 11. The non-volatile memory device 90 has a plurality of data-reading means 94 and provides the reading current Ir to the memory cell 13.

Actually, a data-reading means 94a is connected between the column decoder 19 and the bit line 11a, and between the column decoder 19 and the bit line 11b, provide the reading current Ir to memory cell 13a or memory cell 13b. The data-reading means 94b (not shown) is connected between the column decoder 19 and the bit line 11c (not shown). The data-reading means 94b is also connected between the column decoder 19 and the bit line 11d. The data-reading means 94b provides the reading current Ir to the memory cell 13c (not shown) or the memory cell 13d (not shown).

The data-reading means 94a provides a switching circuit 96a having a switch 95a and switch 95b. The switch 95a connects a second counter 24a and a second current source 23a. The switch 95b connects the second counter 21a and the second current source 23b.

The switching circuit 94a connects the second counter 23a to the second current source 23a, when the switch 95a is on and the switch 95b is off. The switching circuit 95a connects the second counter 25a to the second current source 23b, when the switch 95a is off and the switch 95b is on.

In this way, reading data can be conducted for the memory cell 13 selected by the row decoder 17 and the column decoder 19.

As mentioned above, the non-volatile semiconductor device 90 of this embodiment connect the bit lines 11a, 11b to the data writing means 91a and the data-reading means 94a. As a result, the non-volatile semiconductor device 90 has an advantage to be able to improve increasing a chip size, a speed of writing and reading a number of bit lines, as a number of the writing means and the writing means can be designed with consideration of a balance of writing speed.

Here, it is explained that the data writing means 91a is connected to the two bit line 11a, 11b. Furthermore, it is possible to connect to bit lines more than two. In that case, the switch 92 to connect the first counter 21a to the first current source 20 may be increased. The data-reading means 94a is also carried out as same as the data writing means 91a.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, the first counter and the first buffer in the data-writing means may be unified with the second counter and the second buffer in the data-reading means respectively. Therefore, only one counter and one buffer can be applied to the memory cell. In this case, the counter couples with the buffer, the first current source, the second current source and the potential sensor, respectively. In this approach, a number of the counter and the buffer are decreased, so that the memory area with one counter and one buffer can be shrunk.

What is claimed is:

1. A non-volatile semiconductor memory device, comprising:
a memory cell having a electrolyte film, a first electrode and a second electrode, the electrolyte film being sandwiched between the first electrode and the second electrode, a material of the first electrode being different from a material of the second electrode;
a bit line and a word line being configured as a matrix,
a data-writing means having a first current source and a first counter, the first current source providing the first current to the memory cell, the first counter measuring a providing time of the first current; and
a data-reading means having a second current source, a second counter and a potential sensor, the second current source providing a second current to the memory cell, the second current passing in the opposite direction to the first current, the second counter measuring a providing time of the second current, the potential sensor detecting a potential;
wherein writing data into the memory cell is performed by controlling the providing time of the first current corresponding to the data being written, and reading the data from the memory cell is performed by detecting the providing time of the second current till a potential of the bit line equals to a prescribed potential.

2. The non-volatile semiconductor memory device according to claim 1, further comprising:
a memory cell array having the memory cell, a cell transistor, a common wiring, a row decoder and a column decoder, the cell transistor having a gate, a drain and a source, the gate connecting the word line, the drain connecting the first electrode of the memory cell, the source connecting the bit line, the common wiring connecting the second electrode, the row decoder and the column decoder selecting one of the memory cell in the memory cell array.

3. The non-volatile semiconductor memory device according to claim 1,
wherein the data being written into the selected memory cell and the data being read from the selected memory cell are multilevel data with more than three-value.

4. The non-volatile semiconductor memory device according to claim 1,
wherein the first current and the second current are pulse currents.

5. The non-volatile semiconductor memory device according to claim 1,
wherein the memory cell is reset by providing a third current into the memory cell till the potential of the bit line equals to the prescribed potential before writing the data into the memory cell, the third current passing in the opposite direction to the first current.

6. The non-volatile semiconductor memory device according to claim 1,
wherein the memory cell is refreshed by providing the first current into the memory cell, the first current being controlled by the providing time corresponding to the data being read after reading the data from the memory cell.

7. The non-volatile semiconductor memory device according to claim 1,
wherein a resistance of the memory cell is changed by the first current and the second current so as to act as a memory function.

8. The non-volatile semiconductor memory device according to claim 1,
wherein the first electrode is the same as a first metal contained in the electrolyte film.

9. The non-volatile semiconductor memory device according to claim 1,
wherein the first electrode has a different composition from the electrolyte film including the first metal or the first electrode is a layered structure with the metal layer.

10. The non-volatile semiconductor memory device according to claim 7,
wherein the resistance of the memory cell changes in a stepwise fashion.

11. The non-volatile semiconductor memory device according to claim 7,
wherein a stair of the stepwise resistance is increased with increasing the resistance and is decreased with decreasing the resistance.

12. The non-volatile semiconductor memory device according to claim 3,
wherein each of the multilevel data is determined by difference of the resistance between the stairs in the stepwise fashion.

13. The non-volatile semiconductor memory device according to claim 1, further comprising:
a switching circuit, the switching circuit connecting the memory cell, the switching circuit switching on the connection with the memory cell from the data-writing means to the data-reading means or from the data-reading means to the data-writing means.

14. The non-volatile semiconductor memory device according to claim 1,
wherein each pair of the data-writing portion means and the data-reading means are configured corresponding to each bit line.

15. The non-volatile semiconductor memory device according to claim 1,
wherein each pair of the data-writing means and the data-reading means is configured corresponding to each of the plurality of bit lines.

16. The non-volatile semiconductor memory device, according to claim 2, further comprising:
a semiconductor substrate, the cell transistor being formed on the semiconductor substrate, the memory cell being formed over the semiconductor substrate, the first electrode of the memory cell connecting the source of the cell transistor.

17. The non-volatile semiconductor memory device according to claim 16, further comprising:
a metal being embedded in a through hole formed in an insulator connects between the first electrode and the source, the insulator being formed between the cell transistor and the memory cell.

18. A non-volatile semiconductor memory device, comprising:
a memory cell having a electrolyte film, a first electrode and a second electrode, the electrolyte film being sandwiched between the first electrode and the second electrode, a material of the first electrode being different from a material of the second electrode;
a bit line and a word line being configured as a matrix; and
a data-writing and data-reading means having a first current source, a second current source, a counter and a potential sensor, the first current source providing the first current to the memory cell, the second current source providing a second current to the memory cell, the second current passing in the opposite direction to the first current, the counter measuring a providing time of the first current or the second current, the potential sensor detecting a potential;
wherein writing data into the memory cell is performed by controlling the providing time of the first current corresponding to the data being written, and reading the data from the memory cell is performed by detecting the providing time of the second current till a potential of the bit line equals to a prescribed potential.

19. A method of fabricating a non-volatile semiconductor memory device comprising:
forming a cell transistor on a semiconductor substrate, the cell transistor being covered by an interlayer dielectric layer;
forming a bit line on the interlayer dielectric layer;
forming a contact plug in the interlayer dielectric layer, the contact plug connecting a source of the cell transistor;
forming a memory cell over the bit line via the interlayer dielectric layer, the memory cell having a first electrode, an electrolyte film and a second electrode.

20. The method according to claim 19,
wherein the memory cell has the first electrode, the electrolyte film and the second electrode, the first electrode, the electrolyte film and the second electrode being stacked in order, the first electrode connecting the contact plug so as to couple with the source.
